(19) United States
(12) Patent Application Publication
(10) Pub. No.: US 2026/0017435 A1
(43) Pub. Date: Jan. 15, 2026

(54) TECHNOLOGIES FOR MODELING CARBON DIOXIDE REMOVAL

(71) Applicant: THE TRUSTEES OF INDIANA UNIVERSITY, Bloomington, IN (US)

(72) Inventor: Chen Zhu, Bloomington, IN (US)

(21) Appl. No.: 19/264,502

(22) Filed: Jul. 9, 2025

Related U.S. Application Data
(60) Provisional application No. 63/669,351, filed on Jul. 10, 2024.

(51) Int. Cl. G06F 30/27; B01D 53/62; B01D 53/82

(52) U.S. Cl. CPC G06F 30/27; B01D 53/62; B01D 53/82; B01D 2257/504

(57) ABSTRACT

Technologies for modeling carbon dioxide removal include a compute device with circuitry configured to obtain parameter data for use in modeling carbon dioxide removal from the atmosphere through enhanced rock weathering. The circuitry may also be configured to produce, using one or more models from a library of models, at least one prediction indicative of an amount of carbon dioxide that will be removed through enhanced rock weathering, including simulating co-precipitation of iron with one or more toxic metals. Further, the circuitry may be configured to present a visual representation of the at least one prediction in a user interface. Other embodiments are also described and claimed.

### CROSS-REFERENCE TO RELATED APPLICATIONS

This application claims priority to U.S. Provisional Patent Application No. 63/669,351 filed on Jul. 10, 2024, the disclosure of which is expressly incorporated herein.

### BACKGROUND

Climate change is a growing concern across the world as atmospheric greenhouse gases such as carbon dioxide trap energy radiated from the sun. While a direct result of increases in greenhouse gases is increased temperatures on Earth, knock on effects include droughts, flooding, loss of biodiversity, and disruptions in energy and transportation systems across the world. Through interactions between water and rock (e.g., in soil), carbon dioxide can be captured (e.g., removed) from the atmosphere and correspondingly lessen the effects of climate change. However, given the multitude of factors that influence the complex interactions between water and rock, it is not feasible in conventional computerized systems to reliably determine the amount of carbon dioxide that will be removed in a given location, under a given set of conditions, or to predict side effects of any efforts to enhance the capture of carbon dioxide in the soil. Likewise, conventional systems do not reliably enable a determination of what factors will enable the largest amount of carbon dioxide removal in a given location in the world while satisfying concerns about possible side effects of efforts to enhance the removal of carbon dioxide.

### SUMMARY

The present application discloses one or more of the features recited in the appended claims and/or the following features which, alone or in any combination, may comprise patentable subject matter:

According to an aspect of the present disclosure, a compute device may include circuitry configured to obtain parameter data for use in modeling carbon dioxide removal from the atmosphere through enhanced rock weathering. The circuitry may be further configured to produce, using one or more models from a library of models, at least one prediction indicative of an amount of carbon dioxide that will be removed through enhanced rock weathering. Producing a prediction may include simulating co-precipitation of iron with one or more toxic metals. The circuitry may be further configured to present a visual representation of the at least one prediction in a user interface.

In some embodiments, the circuitry may be configured such that using one or more models from a library of models to produce at least one prediction includes simulating basalt weathering as irreversible reactions with unidirectional rates. The circuitry may also be configured to utilize one or more models in which near-equilibrium rates are one to two orders of magnitude slower than far-from-equilibrium rates. In some embodiments, the circuitry may be configured to utilize one or more models that simulate co-precipitation of iron with toxic metals. The circuitry may be configured to obtain data indicative of properties of soil in a location where the carbon dioxide is to be captured. In some embodiments, the circuitry may be configured such that obtaining data indicative of properties of soil includes obtaining data indicative of minerals in the soil, carbon in the soil, effective porosity, total specific surface area, a height of a top soil layer, an amount of basalt added to the soil, basalt density, bulk soil density, and basalt mineral composition.

The circuitry may be configured such that obtaining parameter data includes obtaining the parameter data as a function of an identification of the location where the carbon dioxide is to be captured. In some embodiments, the circuitry may be configured to obtain parameter data as a function of an identification of the location where the carbon dioxide is to be captured by reading parameter data from a data source of properties of soil associated with location identifiers. In some embodiments, obtaining parameter data includes obtaining parameter data from a data source of mineral compositions for each of multiple basalt feed stocks. The circuitry may be configured to obtain parameter data through user input into corresponding fields of a user interface. In some embodiments, the circuitry may be further configured to calculate, as a function of the obtained parameter data, additional parameter data for use by the one or more models. The circuitry may be configured such that calculating additional parameter data involves calculating air and blind pores, volume of soil per hectare, liters of pore water per hectare, mass of basalt per volume of soil, concentration of basalt, total weight percentage, rock specific surface area, and total surface area.

In some embodiments, calculating additional parameter data further includes utilizing a database of specific surface areas for each of a set of minerals. The compute device, in some embodiments, may include circuitry configured to select one or more models as a function of the obtained parameter data. In some embodiments, the circuitry may be configured such that to select one or more models as a function of the obtained parameter data includes selecting one or more models as a function of a determined similarity of the parameter data to reference parameters for which a corresponding model is identified as having an accuracy that satisfies a defined threshold. In some embodiments, the circuitry is configured such that producing at least one prediction includes selecting one or more models as a function of a distance of a location where the carbon dioxide is to be captured from one or more reference locations associated with the models in the library. In some embodiments, the circuitry is configured such that producing at least one prediction includes reformatting the parameter data for use by the one or more models.

The circuitry may be configured such that producing at least one prediction includes utilizing one or more machine learning models. Additionally or alternatively, the circuitry may be configured utilize an ensemble of models to produce the at least one prediction. In some embodiments, the circuitry may be configured to produce one or more predictions indicative of tons of carbon dioxide captured over a predefined time period. The circuitry may be configured to produce one or more predictions indicative of tons of carbon dioxide captured each year over a defined number of years. In some embodiments, the circuitry may be configured such that to produce at least one prediction involves producing one or more predictions indicative of tons of carbon dioxide captured per unit of area. In some embodiments, the circuitry may be configured to produce one or more predictions indicative of tons of carbon dioxide captured per hectare.

The circuitry may be configured to produce at least one prediction indicative of toxic metal concentrations in water associated with a location where the carbon dioxide is to be captured. In some embodiments, the circuitry may be configured such that to produce at least one prediction indicative of toxic metal concentrations in water involves producing at least one prediction of concentrations of Nickel, Chromium, and Cadmium in the water. In some embodiments, the circuitry is configured such that to produce at least one prediction indicative of toxic metal concentrations in water involves producing the at least one prediction as a function of depth and time. The circuitry may be configured such that to produce the at least one prediction indicative of toxic metal concentrations in water involves producing the at least one prediction relative to one or more regulations pertaining to drinking water or irrigation water associated with the location where the carbon dioxide is to be captured. In some embodiments, the circuitry may be configured such that to produce the at least one prediction involves producing data indicative of a probability or confidence associated with each of multiple predictions.

In some embodiments, the circuitry may be configured such that to produce at least one prediction involves determining an amount of carbon credits associated with the predicted amount of carbon dioxide to be removed from the atmosphere. The compute device, in some embodiments, may have circuitry configured such that to produce at least one prediction involves determining soil parameters to increase capture of carbon dioxide from the atmosphere at a location. In some embodiments, the circuitry may be further configured to determine, from a set of multiple basalt feed stocks, a basalt feed stock predicted to capture the most carbon dioxide at the location while maintaining compliance with one or more regulations associated with the location. In some embodiments, the circuitry is configured such that to present a visual representation of the at least one prediction in a user interface involves presenting a visual representation of the at least one prediction in a web-based interface that includes interactive graphs.

According to another aspect of the present disclosure, a method includes obtaining, by a compute device, parameter data for use in modeling carbon dioxide removal from the atmosphere through enhanced rock weathering. The method may further include producing, by the compute device and using one or more models from a library of models, at least one prediction indicative of an amount of carbon dioxide that will be removed through enhanced rock weathering. In doing so, the method may include simulating co-precipitation of iron with one or more toxic metals. The method may further include presenting, by the compute device, a visual representation of the at least one prediction in a user interface.

In some embodiments, producing, using one or more models from a library of models, at least one prediction includes simulating basalt weathering as irreversible reactions with unidirectional rates. Producing, using one or more models from a library of models, at least one prediction may, in some embodiments, include utilizing one or more models in which near-equilibrium rates are one to two orders of magnitude slower than far-from-equilibrium rates. In some embodiments, producing, using one or more models from a library of models, at least one prediction may include utilizing one or more models that simulate co-precipitation of iron with toxic metals. Obtaining parameter data may, in some embodiments, include obtaining data indicative of properties of soil in a location where the carbon dioxide is to be captured. In some embodiments, obtaining data indicative of properties of soil may include obtaining data indicative of minerals in the soil, carbon in the soil, effective porosity, total specific surface area, a height of a top soil layer, an amount of basalt added to the soil, basalt density, bulk soil density, and a basalt mineral composition.

Obtaining parameter data may include obtaining the parameter data as a function of an identification of the location where the carbon dioxide is to be captured. Obtaining parameter data as a function of an identification of the location where the carbon dioxide is to be captured may include reading parameter data from a data source of properties of soil associated with location identifiers. In some embodiments, obtaining parameter data includes obtaining parameter data from a data source of mineral compositions for each of multiple basalt feed stocks. Obtaining parameter data may include obtaining parameter data through user input into corresponding fields of a user interface. The method may also include calculating, by the compute device and as a function of the obtained parameter data, additional parameter data for use by the one or more models. Calculating additional parameter data may include calculating air and blind pores, volume of soil per hectare, liters of pore water per hectare, mass of basalt per volume of soil, concentration of basalt, total weight percentage, rock specific surface area, and total surface area.

In some embodiments, calculating additional parameter data may additionally include utilizing a database of specific surface areas for each of a set of minerals. Producing at least one prediction may include selecting one or more models as a function of the obtained parameter data. Selecting one or more models as a function of the obtained parameter data may involve selecting one or more models as a function of a determined similarity of the parameter data to reference parameters for which a corresponding model is identified as having an accuracy that satisfies a defined threshold. In some embodiments, producing at least one prediction includes selecting one or more models as a function of a distance of a location where the carbon dioxide is to be captured from one or more reference locations associated with the models in the library. Producing at least one prediction may include reformatting the parameter data for use by the one or more models. In some embodiments, producing at least one prediction involves utilizing one or more machine learning models. Producing at least one prediction may, in some embodiments, include utilizing an ensemble of models to produce the at least one prediction. Producing at least one prediction may include producing one or more predictions indicative of tons of carbon dioxide captured over a predefined time period.

Producing one or more predictions may include producing one or more predictions indicative of tons of carbon dioxide captured each year over a defined number of years. In some embodiments, producing at least one prediction includes producing one or more predictions indicative of tons of carbon dioxide captured per unit of area. Producing one or more predictions may, in some embodiments, include producing one or more predictions indicative of tons of carbon dioxide captured per hectare. In some embodiments, producing at least one prediction includes producing at least one prediction indicative of toxic metal concentrations in water associated with a location where the carbon dioxide is to be captured. Producing at least one prediction indicative of toxic metal concentrations in water may, in some embodiments, involve producing at least one prediction of concentrations of Nickel, Chromium, and Cadmium in the water. In some embodiments, producing at least one prediction indicative of toxic metal concentrations in water involves producing the at least one prediction as a function of depth and time.

Producing the at least one prediction indicative of toxic metal concentrations in water may involve producing the at least one prediction relative to one or more regulations pertaining to drinking water or irrigation water associated with the location where the carbon dioxide is to be captured. In some embodiments, producing the at least one prediction involves producing data indicative of a probability or confidence associated with each of multiple predictions. Producing at least one prediction may include determining an amount of carbon credits associated with the predicted amount of carbon dioxide to be removed from the atmosphere. In some embodiments, producing at least one prediction includes determining soil parameters to increase capture of carbon dioxide from the atmosphere at a location. The method may also include determining, by the compute device and from a set of multiple basalt feed stocks, a basalt feed stock predicted to capture the most carbon dioxide at the location while maintaining compliance with one or more regulations associated with the location. In some embodiments, presenting a visual representation of the at least one prediction in a user interface involves presenting a visual representation of the at least one prediction in a web-based interface that includes interactive graphs.

According to another aspect of the present disclosure, one or more machine-readable storage media may include instructions stored thereon that, in response to being executed, cause a compute device to obtain parameter data for use in modeling carbon dioxide removal from the atmosphere through enhanced rock weathering. The instructions may further cause the compute device to produce, using one or more models from a library of models, at least one prediction indicative of an amount of carbon dioxide that will be removed through enhanced rock weathering, including simulating co-precipitation of iron with one or more toxic metals. Additionally, the instructions may cause the compute device to present a visual representation of the at least one prediction in a user interface. Further, the instructions may cause the compute device to perform any of the methods described above.

Additional features, which alone or in combination with any other feature(s), such as those listed above and/or those listed in the claims, may comprise patentable subject matter and will become apparent to those skilled in the art upon consideration of the following detailed description of various embodiments exemplifying the best mode of carrying out the embodiments as presently perceived.

### BRIEF DESCRIPTION OF THE DRAWINGS

The concepts described herein are illustrated by way of example and not by way of limitation in the accompanying figures. For simplicity and clarity of illustration, elements illustrated in the figures are not necessarily drawn to scale. Where considered appropriate, reference labels have been repeated among the figures to indicate corresponding or analogous elements. The detailed description particularly refers to the accompanying figures in which:

FIG. 1 is a simplified block diagram of at least one embodiment of a system for modeling carbon dioxide removal through enhanced rock weathering;

FIG. 2 is a simplified block diagram of at least one embodiment of a compute device of the system of FIG. 1;

FIGS. 3-7 are flowcharts of at least one embodiment of a method for modeling carbon dioxide removal through enhanced rock weathering that may be performed by the system of FIG. 1;

FIGS. 8 and 9 are user interfaces that may be produced by the system of FIG. 1; and

FIG. 10 is one embodiment of visual representations of the predictions that may be presented by the modeling compute device of the system of FIG. 1, illustrating carbon capture as a function of years;

FIG. 11 is one embodiment of visual representations of the predictions that may be presented by the modeling compute device of the system of FIG. 1, illustrating a simulation of carbon capture as a function of time;

FIG. 12 is one embodiment of visual representations of the predictions that may be presented by the modeling compute device of the system of FIG. 1, illustrating the confidence interval of the simulations over a five year period;

FIG. 13 is one embodiment of visual representations of nickel presence as a function of soil depth as presented by the modeling compute device of the system of FIG. 1; and

FIG. 14 is another embodiment of visual representations of nickel presence as a function of soil depth as presented by the modeling compute device of the system of FIG. 1;

### DETAILED DESCRIPTION OF THE DRAWINGS

While the concepts of the present disclosure are susceptible to various modifications and alternative forms, specific embodiments thereof have been shown by way of example in the drawings and will be described herein in detail. It should be understood, however, that there is no intent to limit the concepts of the present disclosure to the particular forms disclosed, but on the contrary, the intention is to cover all modifications, equivalents, and alternatives consistent with the present disclosure and the appended claims.

References in the specification to “one embodiment,” “an embodiment,” “an illustrative embodiment,” etc., indicate that the embodiment described may include a particular feature, structure, or characteristic, but every embodiment may or may not necessarily include that particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to effect such feature, structure, or characteristic in connection with other embodiments whether or not explicitly described. Additionally, it should be appreciated that items included in a list in the form of “at least one A, B, and C” can mean (A); (B); (C); (A and B); (A and C); (B and C); or (A, B, and C). Similarly, items listed in the form of “at least one of A, B, or C” can mean (A); (B); (C); (A and B); (A and C); (B and C); or (A, B, and C).

The disclosed embodiments may be implemented, in some cases, in hardware, firmware, software, or any combination thereof. The disclosed embodiments may also be implemented as instructions carried by or stored on a transitory or non-transitory machine-readable (e.g., computer-readable) storage medium, which may be read and executed by one or more processors. A machine-readable storage medium may be embodied as any storage device, mechanism, or other physical structure for storing or transmitting information in a form readable by a machine (e.g., a volatile or non-volatile memory, a media disc, or other media device).

In the drawings, some structural or method features may be shown in specific arrangements and/or orderings. However, it should be appreciated that such specific arrangements and/or orderings may not be required. Rather, in some embodiments, such features may be arranged in a different manner and/or order than shown in the illustrative figures. Additionally, the inclusion of a structural or method feature in a particular figure is not meant to imply that such feature is required in all embodiments and, in some embodiments, may not be included or may be combined with other features.

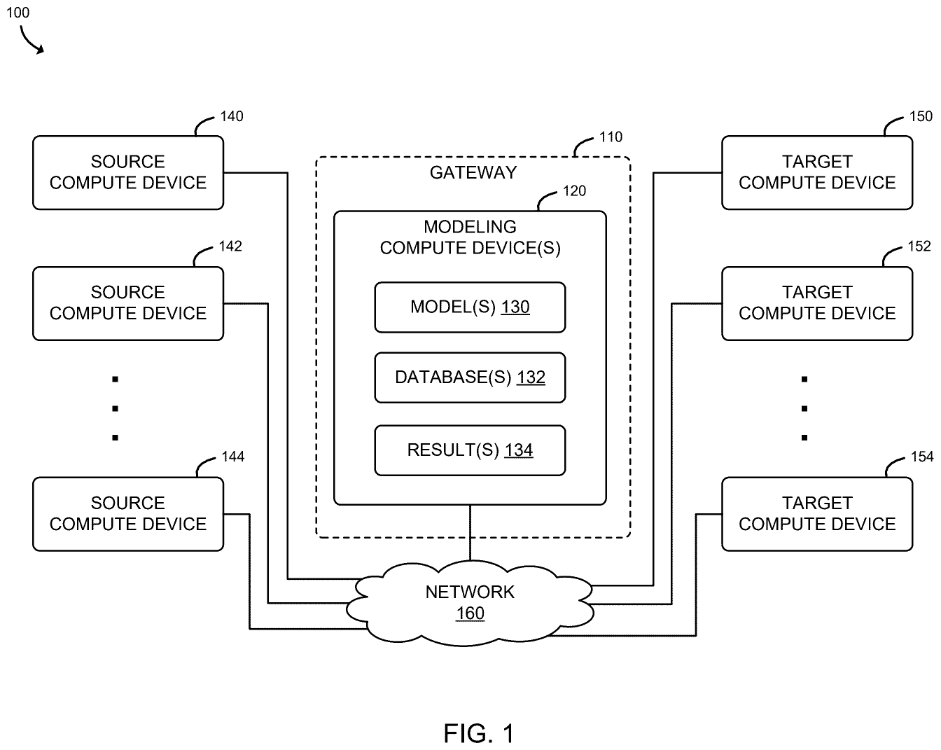

Referring now to FIG. 1, a system 100 for modeling carbon dioxide removal through enhanced rock weathering includes a set of one or more modeling compute devices 120, a set of source compute devices 140, 142, 144 and a set of target compute devices 150, 152, 154. In operation, the modeling compute devices 120 operate as a gateway 110 through which end users (e.g., scientists, organizations, etc.) of operating target compute devices 150, 152, 154 may view predictions (e.g., forecasts) of how much carbon dioxide will be captured in the soil at a particular location through a process of enhanced rock weathering. In enhanced rock weathering, rock, such as basalt, is added to soil at a location (e.g., one or more hectares of land) in a powdered form to increase the amount of carbon dioxide removed from the atmosphere through interaction between the carbon dioxide, water (e.g., rain), and rock. The composition of the basalt (e.g., mineral composition) as well as properties of the soil itself (e.g., porosity, carbon content, minerals, etc.) influence the amount of carbon dioxide that will be captured and may impact an amount of toxic metals present in the soil and/or water in the location as a result of the chemical processes involved in the capture of the carbon dioxide. As such, given the multitude of factors that can influence the amount of carbon dioxide removal, the modeling compute devices 120 may utilize a library of models 130 (e.g., thousands of models) and a database 132 of properties of minerals that also affect the amount of carbon dioxide that will be captured. The modeling compute devices 120 produce results 134, which may be embodied as data indicative of amount of carbon dioxide that will be captured under the specified conditions. Additionally, the results 134 may indicate the amount of toxic metals that are predicted to be present in the soil and water as a result of the chemical processes. Further, the results may be broken down across multiple years, depths, confidence intervals, or other parameters and may be the product of thousands of simulations using the set of models 130.

The source compute devices 140, 142, 144 may provide data indicative of properties of the soil in various locations, properties of basalt (e.g., various feed stocks of basalt), information indicative of a carbon credits market (e.g., an amount of carbon credits associated with an amount of carbon captured or removed from the atmosphere), data indicative of regulations associated with various locations (e.g., drinking water regulations, irrigation water regulations, soil regulations), and/or other data usable by the modeling compute devices 120 in simulating the capture of carbon from the atmosphere through enhanced rock weathering processes.

In the illustrative embodiment, the system 100 provides a science gateway (e.g., the gateway 110) for forecasting the efficacy of enhanced rock weathering, predicting and quantifying carbon dioxide removal as well as toxic metal release into waters and soils. The system 100, in operation, provides innovative and independent geochemical models and modeling forecasts, filling a current gap in monitoring, reporting, and verification (MRV). Further, the system 100 contributes to the trust that is necessary for the scale-up of climate-tech carbon dioxide removal (CDR) industries to the gigaton level. While the system 100, in some embodiments, focuses on enhanced rock weathering, the science and technologies can also be applied to storing carbon dioxide in basalt and sandstone aquifers and mine tailings.

A modeling forecast is useful at every stage of a project: conceptualization, contract negotiation, application, and post-project monitoring. The gateway 110, in the illustrative embodiment, is cloud-based, documented, and based on advanced cyberinfrastructure and data sciences that transform how modeling is delivered and how results are archived, analyzed, and presented. The gateway 110, in the illustrative embodiment, provides industry-standard authentication, authorization, and controlled sharing capabilities. Further, the system 100 provides provenance for the execution of tools, clonability, and reusability and integrates with national open cyberinfrastructure and public clouds for workflow execution.

In the illustrative embodiment, the gateway 110 may serve four types of clients: a) technical specialists at stakeholders (CDR and purchaser corporations, regulatory agencies, environmental groups) who can search a large library of models 130 to find the likely outcomes for their projects; b) geochemical experts who can develop or tweak their models 130 on the gateway 110, but aided by automatic documentation, archives, and traceability on the gateway; c) stakeholders with no in-house capabilities who wish to outsource the initial development of models 130 and run the models 130 on the gateway 110; d) stakeholders who need independent models as certification. The availability of the gateway 110 may operate to broaden the participation of underrepresented groups and less developed countries, helping achieve the common goal of implementing scalable solutions around the world.

Enhanced rock weathering can be generally represented with the equations shown below:

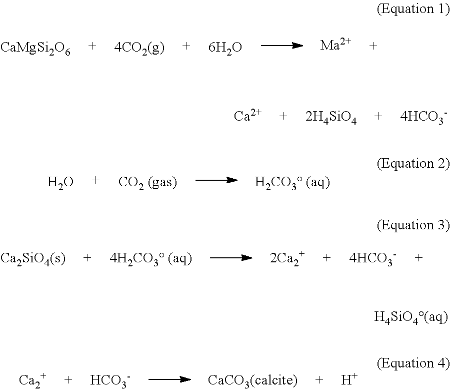

Other equations representative of geochemical reactions are set forth in “Environmental Applications of Geochemical Modeling” by Chen Zhu and Greg Anderson, published in 2002, the contents of which are incorporated herein by reference. As discussed herein, characteristics of the soil and basalt in the soil can significantly impact the amount of carbon dioxide that will be captured and the amounts of metals (e.g., toxic metals) that may be introduced into the soil and water through the enhanced rock wreathing process. The models 130, in the illustrative embodiment, account for the characteristics through parameters discussed herein. Further, the models 130 incorporate features that are not present in conventional modeling systems, including the following: a. Near-equilibrium rates (e.g., in systems with relatively low Gibbs energy) are modeled to be one to two orders of magnitude slower than the far-from-equilibrium rates (e.g., in systems with relatively high Gibbs energy), rather than the far-from-equilibrium rate constants used in other models; b. basalt weathering is simulated as irreversible reactions with unidirectional rates (not reversible reactions in other models, which are theoretically wrong); and c. the models 130 include co-precipitation of toxic metals released from enhanced rock weathering with iron oxyhydroxides. Without co-precipitation in the models 130, the forecasts of toxic metal released into soil may incorrectly indicate toxic metal amounts in excess of applicable regulations. The models 130 may be fine-tuned with time, and more components may be added to the model 130.

Further, the system 100, in the illustrative embodiment, provides a web-based model interface. Geochemical models are generally inaccessible to non-experts and the number of experts in the world is in short supply. The system 100 leverages expertise and experience of experts and makes modeling and modeling results available to non-experts. The gateway 110, in the illustrative embodiment, utilizes a database (e.g., the database 132) of mineralogical compositions of basalt feed stocks to be applied to croplands, and provides a web tool (e.g., a web based user interface) that allows users to input mineralogical compositions of the specific feed stock. Behind the web interface, the gateway 110 utilizes a database (e.g., the database 132) of different specific surface areas for different minerals. In operation, the gateway 110 may perform automatic input file generation (e.g., reformatting of parameter data into a format usable by the models 130).

The web interface and models enable users (e.g., operating the target compute devices 150, 152, 154) to combine different parameters and run different scenarios to view resulting predictions of carbon capture through enhanced rock weathering and side effects thereof. For example, users may compare how much carbon dioxide is captured by applying 100 tons of basalt per hectare versus ten tons of basalt per hectare, and using one feed stock of basalt (e.g., Oregon basalt) versus another feed stock of basalt (e.g., Columbia River basalt). Users may also view the differences in carbon capture given different particle sizes. Further, users may view data that is indicative of toxic metal release into water and soil under varying conditions.

In the illustrative embodiment, the gateway 110 may maintain a library of millions of simulations with a wide range of field conditions. The library may be searchable and the gateway 110 may enable users to locate modeling results and graphic presentations that fit their field conditions within minutes, rather than waiting for hours or longer for simulation results. The library may serve as a base for development or improvement of machine learning algorithms to (1) accelerate the simulations; and (2) find patterns, which lead to faster, more accurate, and more interpretable models. The models 130, in the illustrate embodiment, are calibrated geochemical models that bridge the gap between laboratory and field-based estimates of geochemical reactions. In particular, the models 130 may be calibrated with enhanced rock weathering batch scale laboratory experimental data, field data, and lysimeter experimental data. The results 134 may be embodied as databases and input files with adjusted parameters or semi-empirical scaling factors. In effect, the gateway 110 may provide independent, rigorous, models and modeling results that come with trust and creditability.

While a relatively small number of compute devices 120, 140, 142, 144, 150, 152, 154 are shown in FIG. 1 for simplicity and clarity, it should be understood that the number of compute devices, in practice, may range in the tens, hundreds, thousands, or more. Likewise, it should be understood that the compute devices 120, 140, 142, 144, 150, 152, 154 may be distributed differently or perform different roles than the configuration shown in FIG. 1. Further, though shown as separate compute devices 120, 140, 142, 144, 150, 152, 154 in some embodiments, the functionality of one or more of the compute devices 120, 140, 142, 144, 150, 152, 154 may be combined into fewer compute devices and/or distributed across more compute devices than those shown in FIG. 1.

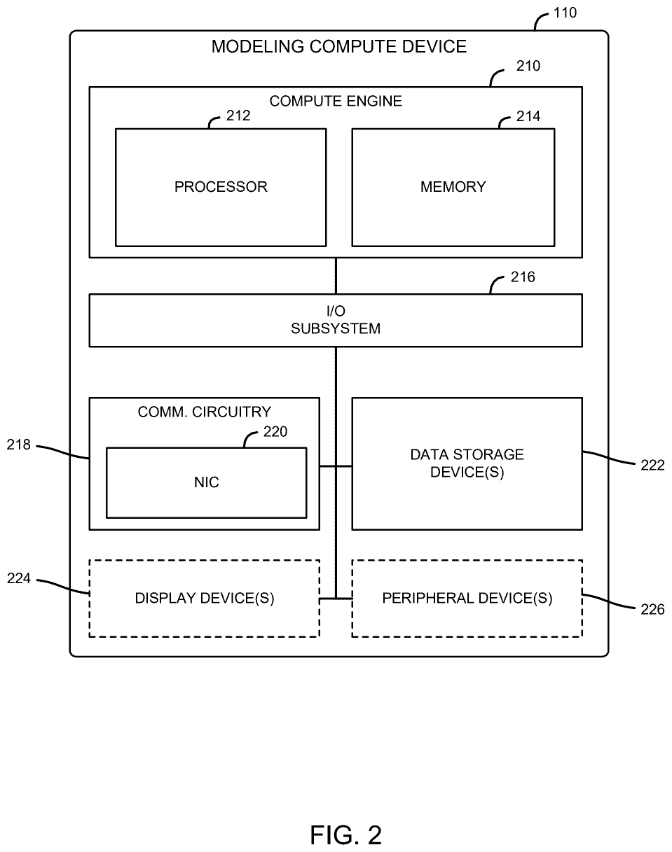

Referring now to FIG. 2, an illustrative embodiment of a modeling compute device 120 includes a compute engine 210, an input/output (I/O) subsystem 216, communication circuitry 218, and one or more data storage devices 222. In some embodiments, the modeling compute device 120 may include one or more display devices 224 and/or one or more peripheral devices 226 (e.g., a mouse, a physical keyboard, etc.). In some embodiments, one or more of the illustrative components may be incorporated in, or otherwise form a portion of, another component. The compute engine 210 may be embodied as any type of device or collection of devices capable of performing various compute functions described below. In some embodiments, the compute engine 210 may be embodied as a single device such as an integrated circuit, an embedded system, a field-programmable gate array (FPGA), a system-on-a-chip (SOC), or other integrated system or device. Additionally, in the illustrative embodiment, the compute engine 210 includes or is embodied as a processor 212 and a memory 214. The processor 212 may be embodied as any type of processor capable of performing the functions described herein. For example, the processor 212 may be embodied as a single or multi-core processor(s), a microcontroller, or other processor or processing/controlling circuit. In some embodiments, the processor 212 may be embodied as, include, or be coupled to an FPGA, an application specific integrated circuit (ASIC), reconfigurable hardware or hardware circuitry, or other specialized hardware to facilitate performance of the functions described herein.

In embodiments, the processor 212 is capable of receiving, e.g., from the memory 214 or via the I/O subsystem 216, a set of instructions which when executed by the processor 212 cause the modeling compute device 120 to perform one or more operations described herein. In embodiments, the processor 212 is further capable of receiving, e.g., from the memory 214 or via the I/O subsystem 216, one or more signals from external sources, e.g., from the peripheral devices 226 or via the communication circuitry 218 from an external compute device, external source, or external network. As one will appreciate, a signal may contain encoded instructions and/or information. In embodiments, once received, such a signal may first be stored, e.g., in the memory 214 or in the data storage device(s) 222, thereby allowing for a time delay in the receipt by the processor 212 before the processor 212 operates on a received signal. Likewise, the processor 212 may generate one or more output signals, which may be transmitted to an external device, e.g., an external memory or an external compute engine via the communication circuitry 218 or, e.g., to one or more display devices 224. In some embodiments, a signal may be subjected to a time shift in order to delay the signal. For example, a signal may be stored on one or more storage devices 222 to allow for a time shift prior to transmitting the signal to an external device. One will appreciate that the form of a particular signal will be determined by the particular encoding a signal is subject to at any point in its transmission (e.g., a signal stored will have a different encoding than a signal in transit, or, e.g., an analog signal will differ in form from a digital version of the signal prior to an analog-to-digital (A/D) conversion).

The main memory 214 may be embodied as any type of volatile (e.g., dynamic random access memory (DRAM), etc.) or non-volatile memory or data storage capable of performing the functions described herein. Volatile memory may be a storage medium that requires power to maintain the state of data stored by the medium. In some embodiments, all or a portion of the main memory 214 may be integrated into the processor 212. In operation, the main memory 214 may store various software and data used during operation such as models, databases, simulation results, applications, libraries, and drivers.

The compute engine 210 is communicatively coupled to other components of the modeling compute device 120 via the I/O subsystem 216, which may be embodied as circuitry and/or components to facilitate input/output operations with the compute engine 210 (e.g., with the processor 212 and the main memory 214) and other components of the modeling compute device 120. For example, the I/O subsystem 216 may be embodied as, or otherwise include, memory controller hubs, input/output control hubs, integrated sensor hubs, firmware devices, communication links (e.g., point-to-point links, bus links, wires, cables, light guides, printed circuit board traces, etc.), and/or other components and subsystems to facilitate the input/output operations. In some embodiments, the I/O subsystem 216 may form a portion of a system-on-a-chip (SoC) and be incorporated, along with one or more of the processor 212, the main memory 214, and other components of the modeling compute device 120, into the compute engine 210.

The communication circuitry 218 may be embodied as any communication circuit, device, or collection thereof, capable of enabling communications over a network between the modeling compute device 120 and another device (e.g., a compute device 140, 142, 144, 150, 152, 154, etc.). The communication circuitry 218 may be configured to use any one or more communication technology (e.g., wired or wireless communications) and associated protocols (e.g., Ethernet, Wi-Fi®, WiMAX, Bluetooth®, etc.) to effect such communication.

The illustrative communication circuitry 218 includes a network interface controller (NIC) 220. The NIC 220 may be embodied as one or more add-in-boards, daughter cards, network interface cards, controller chips, chipsets, or other devices that may be used by the modeling compute device 120 to connect with another compute device (e.g., a compute device 140, 142, 144, 150, 152, 154, etc.). In some embodiments, the NIC 220 may be embodied as part of a system-on-a-chip (SoC) that includes one or more processors, or included on a multichip package that also contains one or more processors. In some embodiments, the NIC 220 may include a local processor (not shown) and/or a local memory (not shown) that are both local to the NIC 220. Additionally or alternatively, in such embodiments, the local memory of the NIC 220 may be integrated into one or more components of the modeling compute device 120 at the board level, socket level, chip level, and/or other levels.

Each data storage device 222, may be embodied as any type of device configured for short-term or long-term storage of data such as, for example, memory devices and circuits, memory cards, hard disk drives, solid-state drives, or other data storage device. Each data storage device 222 may include a system partition that stores data and firmware code for the data storage device 222 and one or more operating system partitions that store data files and executables for operating systems.

Each display device 224 may be embodied as any device or circuitry (e.g., a liquid crystal display (LCD), a light emitting diode (LED) display, a cathode ray tube (CRT) display, etc.) configured to display visual information (e.g., text, graphics, etc.) to a user. In some embodiments, a display device 224 may be embodied as a touch screen (e.g., a screen incorporating resistive touchscreen sensors, capacitive touchscreen sensors, surface acoustic wave (SAW) touchscreen sensors, infrared touchscreen sensors, optical imaging touchscreen sensors, acoustic touchscreen sensors, and/or other type of touchscreen sensors) to detect selections of on-screen user interface elements or gestures from a user.

In the illustrative embodiment, the components of the modeling compute device 120 are housed in a single unit. However, in other embodiments, the components may be in separate housings, in separate racks of a data center, and/or spread across multiple data centers or other facilities. The compute devices 140, 142, 144, 150, 152, 154 may have components similar to those described in FIG. 2 with reference to the modeling compute device 120. The description of those components of the modeling compute device 120 is equally applicable to the description of components of the compute devices 140, 142, 144, 150, 152, 154. Further, it should be appreciated that any of the devices 120, 140, 142, 144, 150, 152, 154 may include other components, sub-components, and devices commonly found in a computing device, which are not discussed above in reference to the modeling compute device 120 and not discussed herein for clarity of the description.

In the illustrative embodiment, the compute devices 120, 140, 142, 144, 150, 152, 154 are in communication via a network 160, which may be embodied as any type of wired or wireless communication network, including global networks (e.g., the internet), wide area networks (WANs), local area networks (LANs), digital subscriber line (DSL) networks, cable networks (e.g., coaxial networks, fiber networks, etc.), cellular networks (e.g., Global System for Mobile Communications (GSM), Long Term Evolution (LTE), Worldwide Interoperability for Microwave Access (WiMAX), 3G, 4G, 5G, etc.), a radio area network (RAN), or any combination thereof.

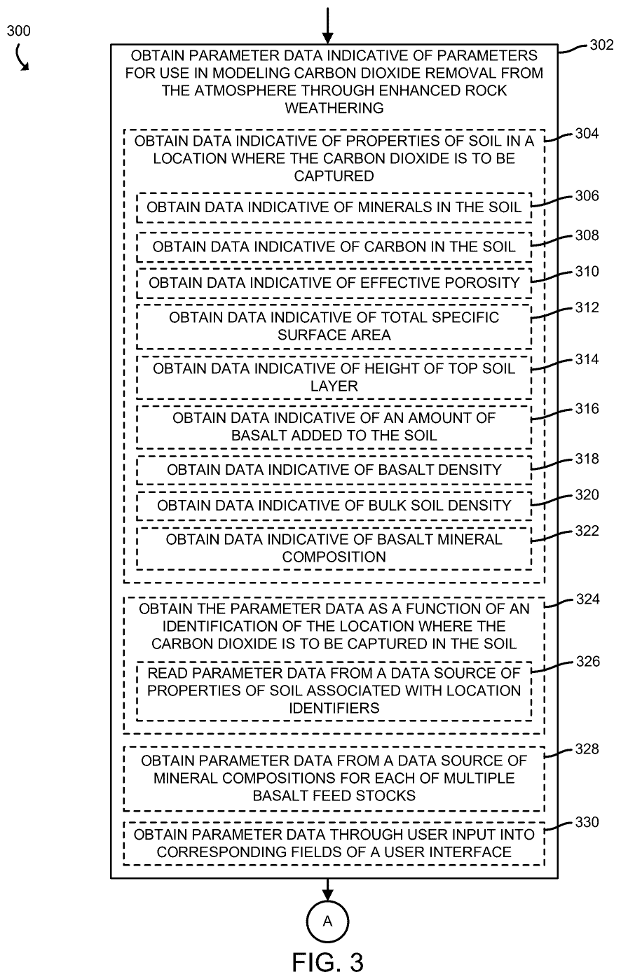

Referring now to FIG. 3, the system 100 (e.g., a modeling compute device 120 of the gateway 110) may perform a method 300 for modeling carbon dioxide removal through enhanced rock weathering. The method 300, in the illustrative embodiment, begins with block 302 in which the modeling compute device 120 obtains parameter data indicative of parameters for use in modeling carbon dioxide removal from the atmosphere through enhanced rock weathering (e.g., the application of basalt dust to soil to increase the amount of carbon dioxide captured through the interaction of water (e.g., rain), carbon dioxide, and rock (e.g., the basalt dust)). In doing so, and as indicated in block 304, the modeling compute device 120 obtains data indicative of properties of soil in a location where the carbon dioxide is to be captured (e.g., removed from the atmosphere through enhanced rock weathering). In the illustrative embodiment, the modeling compute device 120 may obtain data indicative of minerals in the soil (e.g., a numeric value, such as a number indicative of a percentage of the soil comprising minerals), as indicated in block 306. As indicated in block 308, the modeling compute device 120 may obtain data indicative of carbon in the soil (e.g., a numeric value indicative of a percentage of the soil comprising carbon).

The modeling compute device 120 may additionally obtain data indicative of effective porosity of the soil where the carbon is to be captured, as indicated in block 310. The effective porosity may be expressed, in at least some embodiments, as a numeric value (e.g., a percentage). As indicated in block 312, the modeling compute device 120 may obtain parameter data indicative of total specific surface area. In at least some embodiments, the total specific surface area may be expressed as square meters per gram. The modeling compute device 120 may obtain data indicative of the height of a top soil layer, as indicated in block 314. The height, in the illustrative embodiment, is expressed in meters. Further, the modeling compute device 120 may obtain data indicative of an amount of basalt added to the soil (e.g., tons per hectare), as indicated in block 316. Further, the modeling compute device 120 may obtain data indicative of basalt density, such as in grams per cubic centimeter, as indicated in block 318. Additionally, the modeling compute device 120 may obtain data indicative of bulk soil density, as indicated in block 320. The bulk soil density, in at least some embodiments, may be expressed as grams per cubic centimeter. The modeling compute device 120 may also obtain data indicative of basalt mineral composition, as indicated in block 322. The mineral composition of the basalt may be structured as one or more pairs of values, with each pair including an identifier (e.g., name, abbreviation, etc.) of a mineral and a corresponding percentage (e.g., indicative of a percentage of the basalt feed stock that the mineral constitutes).

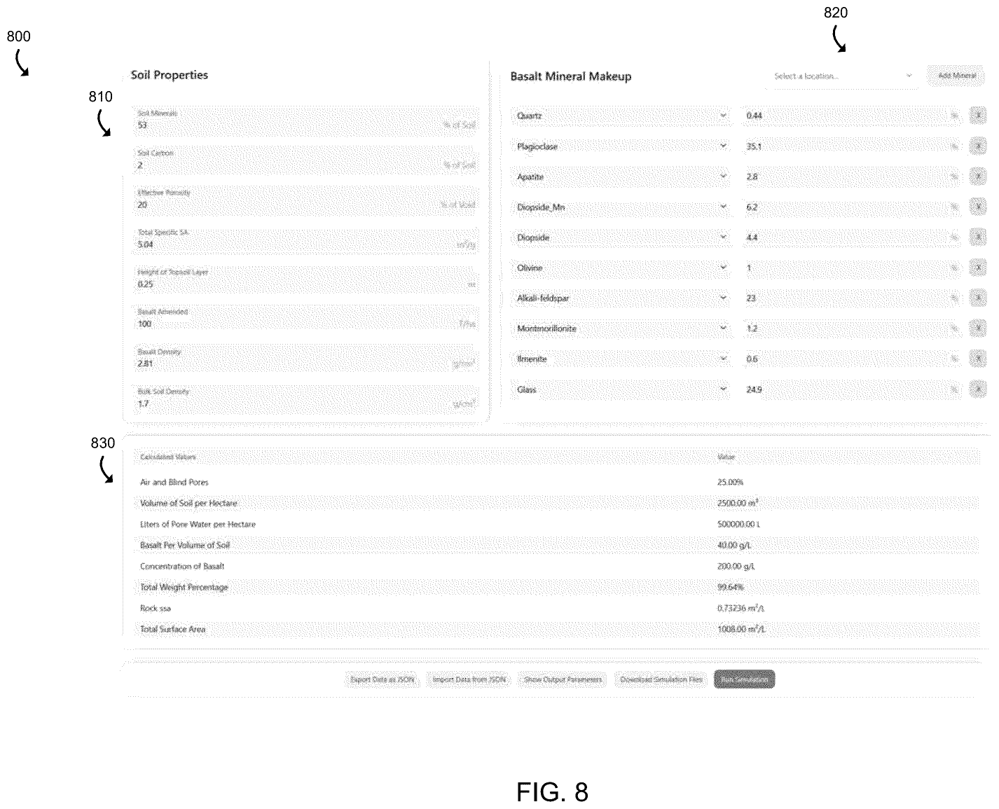

Still referring to FIG. 3, the modeling compute device 120 may obtain the parameter data as a function of (e.g., based on) an identification of the location where the carbon dioxide is to be captured in the soil, as indicated in block 324. In doing so, the modeling compute device 120 may read parameter data from a data source (e.g., a database 132, a data set transmitted from a source compute device 140, 142, 144, etc.) of properties of soil associated with location identifiers (e.g., plot numbers, geographic coordinates, zip codes, etc.), as indicated in block 326. In some embodiments, the modeling compute device 120 may obtain parameter data from a data source (e.g., a database 132, a data set transmitted from a source compute device 140, 142, 144, etc.) of mineral compositions from each of multiple basalt feed stocks, as indicated in block 328. Additionally or alternatively, the modeling compute device 120 may obtain parameter data through user input into corresponding fields (e.g., text boxes, check boxes, etc.) of a user interface (e.g., a graphical user interface presented by a target compute device 150, 152, 154 based on code (e.g., hypertext markup language (HTML) and/or JavaScript) and images (e.g., portable network graphics (PNG) files, Joint Photographic Experts Group (JPEG) files, or the like) transmitted from the modeling compute device 120 to the target compute device(s) 150, 152, 154 via the network 160, as indicated in block 330. An embodiment of a user interface 800 with which the modeling compute device 120 may obtain parameter data is shown in FIG. 8. The user interface 800 includes a first screen 810 that comprises parameter data about soil properties and a second screen 820 that includes parameter data about basalt mineral makeup. The user interface 800 provides one embodiment that users can use to input parameters related to soil properties and basalt mineral composition, run the models, and calculate how much CO₂ can be sequestered.

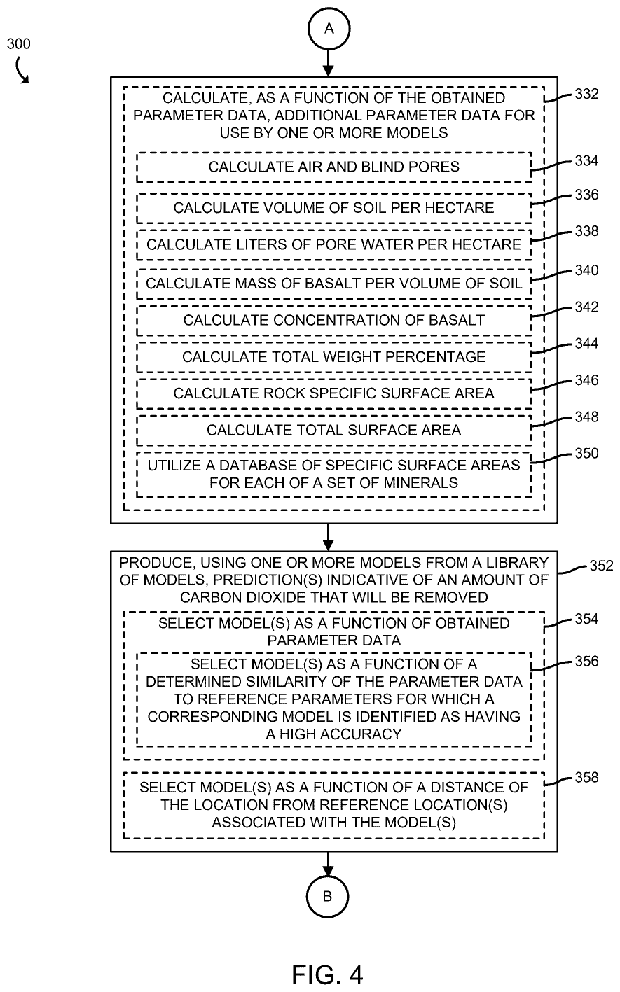

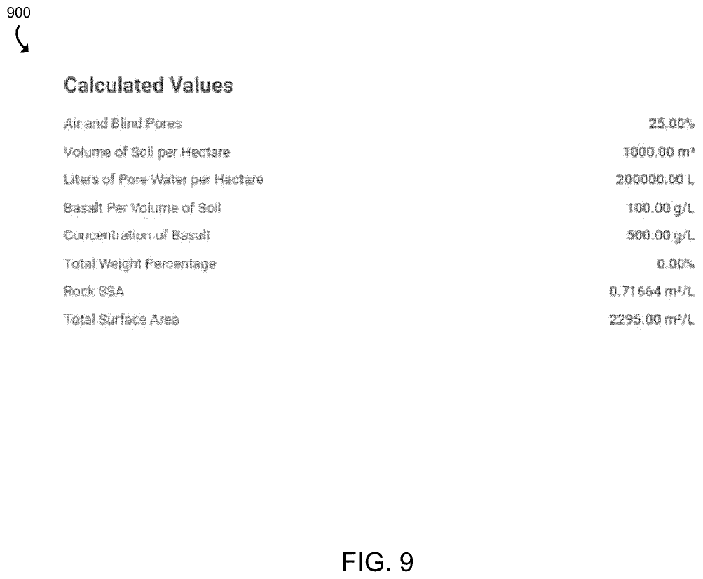

Referring now to FIG. 4, the method 300 continues in block 332 in which the modeling compute device 120 may calculate, as a function of the obtained parameter data, additional parameter data for use by one or more models (e.g., the models 130). In doing so, the modeling compute device 120 may calculate air and blind pores (e.g., a numeric value), as indicated in block 334. The modeling compute device 120 may additionally calculate a volume of soil per hectare, as indicated in block 336. Further, the modeling compute device 120 may calculate a number of volume (e.g., liters) of pore water per unit of area (e.g., hectare), as indicated in block 338. Additionally, the modeling compute device 120 may calculate a mass of basalt per unit of volume of the soil, as indicated in block 340. In addition, the modeling compute device 120 may calculate a concentration of basalt in the soil, as indicated in block 342. Further, the modeling compute device 120 may calculate a total weight percentage, as indicated in block 344. The modeling compute device 120 may also calculate a rock specific surface area, as indicated in block 346. In addition, the modeling compute device 120 may calculate a total surface area, in block 348. In performing the calculations, the modeling compute device 120 may utilize a database (e.g., a database 132) of specific surface areas for each of a set of minerals (e.g., minerals in the soil, in the basalt, etc.), as indicated in block 350. An embodiment of a user interface 900 in which the modeling compute device 120 may display additional parameters calculated as discussed above is shown in FIG. 9. In some embodiments, the user interface 800 includes a third screen 830 that may display additional parameters calculated as discussed above.

After obtaining the parameter data, the method 300, in the illustrative embodiment, advances to block 352, in which the modeling compute device 120 produces, using one or models from a library of models (e.g., the models 130), one or more predictions indicative of an amount of carbon dioxide that will be removed from the atmosphere (e.g., captured through enhanced rock weathering). In doing so, the modeling compute device 120 may select one or more models 130 as a function of the obtained parameter data, as indicated in block 354. That is, the modeling compute device 120 may select one or more models 130 from the library of models as a function of a determined similarity (e.g., a similarity score, such as a calculated distance (e.g., a Euclidean distance, a cosine similarity, a result of a clustering analysis, etc.)) of the parameter data (e.g., obtained in block 302) to reference parameters for which one or more corresponding models 130 have been identified (e.g., in a data set in the memory 214 or storage 222, in a database 132, etc.) as having a high accuracy of predictions (e.g., the results 134 produced by those models have been shown to predict within a predefined threshold of accuracy (e.g., a defined percentage), actual results that were later measured in field tests). That is, if a particular model 130 is identified as more accurately predicting the amount of carbon dioxide that will be removed from the atmosphere than other models, when the parameters are similar to those obtained in block 302, the modeling compute device 120 may select that model for use.

In some embodiments, as indicated in block 358, the modeling compute device 120 may select one or more models 130 as a function of a distance of the location where the carbon dioxide is to be captured to each of a set of reference locations associated with the models 130. That is, a data set (e.g., in the memory 214, the data storage 222, or a database 132) may identify a location (e.g., a zip code, a set of geographic coordinates, or other identifier of a location) with each model 130 in the library (e.g., because the corresponding model 130 has been shown to produce predictions with high accuracy for the associated location) and the modeling compute device 120 may select a set (e.g., one or more) of the models 130 that are closest to the location where the carbon dioxide is to be captured.

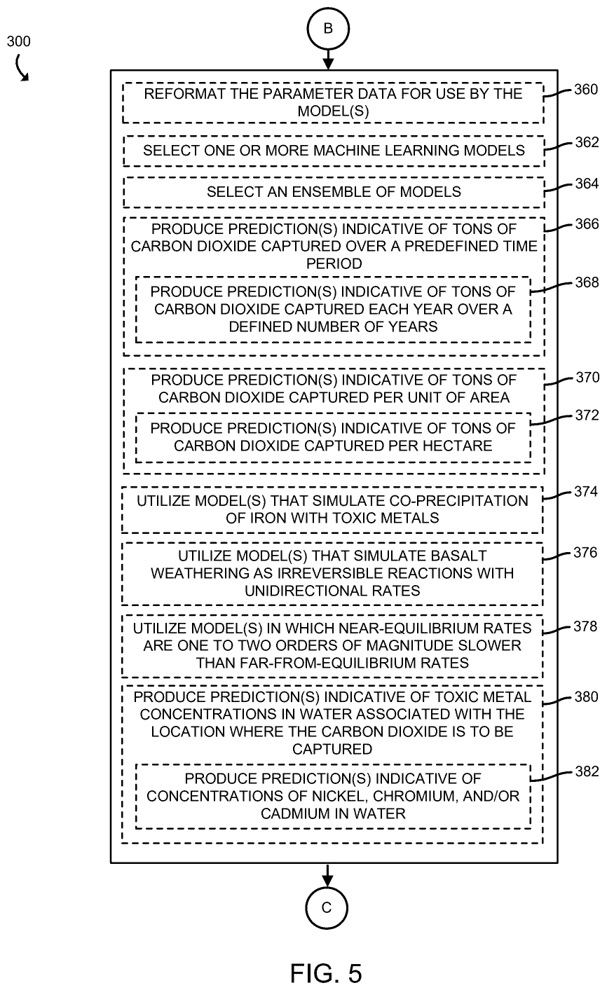

Referring now to FIG. 5, in block 360, the modeling compute device 120 may reformat the parameter data for use by the models 130 (e.g., by converting the data into a file format that the models 130 are configured to parse (e.g., using a scripting language such as Python)). As indicated in block 362, the modeling compute device 120 may select one or more machine learning models (e.g., models, such as neural networks, decision trees, or others that may iteratively improve in prediction accuracy based on feedback). In some embodiments, the modeling compute device 120 may select an ensemble (e.g., a combination of models, in which outputs of the individual models may be weighted relative to each other), as indicated in block 364. The models 130 may include one or more models implemented by PHREEQC (e.g., PHREEQC 3), from the U.S. Geological Survey, GEM (e.g., reservoir modeling), TOUGHREACT from Lawrence Berkeley National Laboratory, and/or other models (e.g., provided by entities associated with one or more of the source compute devices 140, 142, 144). The modeling compute device 120 may produce one or more predictions indicative of tons of carbon dioxide captured over a predefined time period, as indicated in block 366. In doing so, the modeling compute device 120 may produce one or more predictions indicative of tons of carbon dioxide that will be captured each year of a defined number of years at the specified location, as indicated in block 368.

The modeling compute device 120 may produce one or more predictions indicative of tons of carbon dioxide that will be captured per unit of area, as indicated in block 370. In doing so, the modeling compute device 120 may produce one or more predictions indicative of tons of carbon dioxide that will be captured per hectare, as indicated in block 372. In the illustrative embodiment, and unlike conventional systems, the modeling compute device 120 utilizes models that simulate co-precipitation of iron with toxic metals, as indicated in block 374. Additionally, and unlike conventional systems, the modeling compute device 120, in the illustrative embodiment, utilizes models that simulate basalt weathering as irreversible reactions with unidirectional rates, as indicated in block 376. Further, and unlike conventional systems, the modeling compute device 120 in the illustrative embodiment utilizes models in which near-equilibrium (e.g., within a defined percentage of an equilibrium state) rates are one to two orders of magnitude slower than far-from-equilibrium (e.g., not within the defined percentage of the equilibrium state) rates, as indicated in block 378. Further, and as indicated in block 380, the modeling compute device 120, in the illustrative embodiment, produces one or more predictions indicative of toxic metal concentrations in water associated with the location where the carbon dioxide is to be captured. In doing so, the modeling compute device 120 may produce one or more predictions indicative of concentrations of Nickel, Chromium, and/or Cadmium in the water, as indicated in block 382.

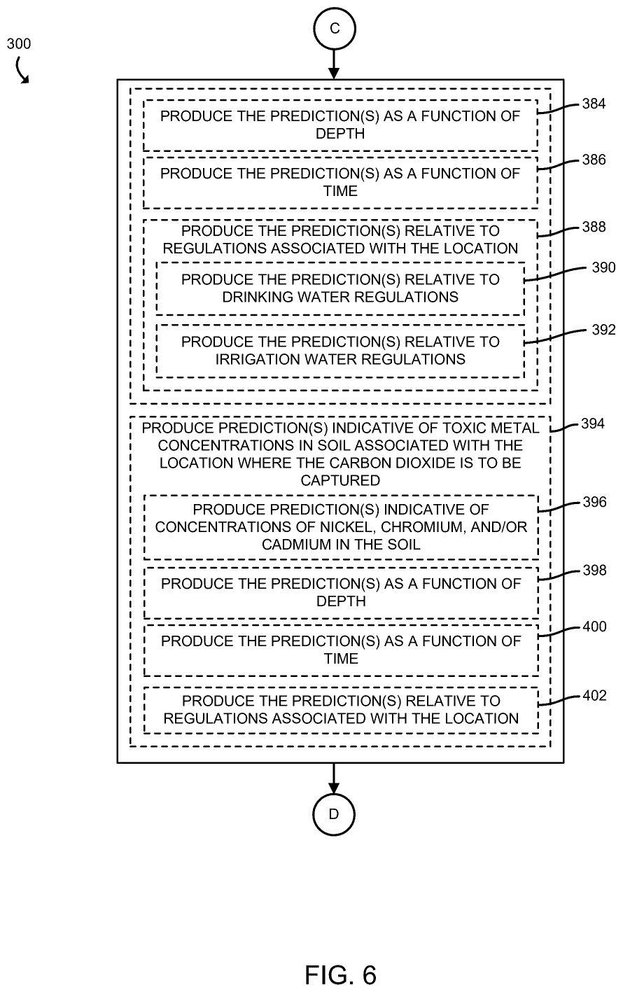

Referring now to FIG. 6, the modeling compute device 120 may produce the one or more predications as a function of depth (e.g., depth of the water), as indicated in block 384. As indicated in block 386, the modeling compute device 120 may produce the one or more predictions regarding toxic metals in the water as a function of time (e.g., amount of toxic metals in the water per year). In some embodiments, the modeling compute device 120 may produce the predictions of toxic metals in the water relative to one or more regulations associated with the location where the carbon dioxide is to be captured, as indicated in block 388. That is, the modeling compute device 120 may obtain data (e.g., from a database 132, from a source compute device 140, 142, 144) indicative of applicable regulations and indicate whether the predicted amount of toxic metals satisfies (e.g., does not violate the regulation(s), is close to (e.g., within a defined percentage of), etc.) a limit specified by the regulations. The modeling compute device 120 may produce the prediction(s) relative to drinking water regulations and/or irrigation water regulations, as indicated in blocks 390, 392. The modeling compute device 120 may produce one or more predictions indicative of toxic metal concentrations in the soil associated with the location where the carbon dioxide is to be captured, as indicated in block 394. In doing so, the modeling compute device 120 may produce prediction(s) indicative of concentrations of Nickel, Chromium, and/or Cadmium in the soil, as indicated in block 396. The modeling compute device 120 may produce the prediction(s) as a function of depth (e.g., in the soil) and/or as a function of time, as indicated in blocks 398, 400. Similar to block 388, the modeling compute device 120 may produce the prediction(s) of toxic metals in the soil relative to one or more regulations associated with the location, as indicated in block 402.

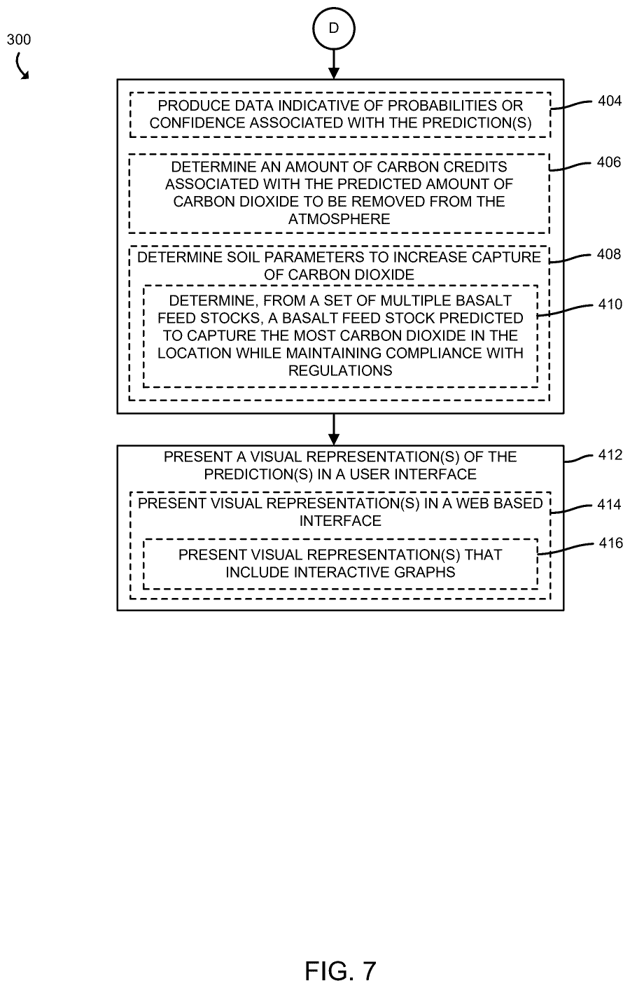

Referring now to FIG. 7, the modeling compute device 120 may produce data indicative of probabilities (e.g., confidence) associated with the one or more predictions, as indicated in block 404. For example, the modeling compute device 120 may produce a predictions as confidence intervals, with one prediction associated with a particular level of confidence (e.g., a percentage of likelihood), and one or more other predictions associated with other levels of confidence. As indicated in block 406, the modeling compute device 120 may determine an amount of carbon credits associated with the predicted amount of carbon dioxide to be removed from the atmosphere. For example, the modeling compute device 120 may obtain data (e.g., from a source compute device 140, 142, 144, a database 132, etc.) indicative of a conversion rate between tons of carbon captured and a number of corresponding carbon credits and multiply the predicted amount of carbon dioxide by the conversion rate to determine the amount of carbon credits. In some embodiments, the modeling compute device 120 may adjust the number of carbon credits based on a probability or confidence level associated with the predicted amount of carbon dioxide to be removed from block 404 (e.g., by multiplying the amount of carbon dioxide by a percentage associated with the probability or confidence level). As indicated in block 408, the modeling compute device 120 may determine soil parameters that will increase capture of carbon dioxide at the location. For example, and as indicated in block 410, the modeling compute device 120 may determine, from a set of multiple basalt feed stocks, each having different mineral compositions and/or other properties, a basalt feed stock predicted to capture the most carbon dioxide in the location while maintaining compliance with regulations (e.g., toxic metals in the soil, toxic metals in the water). The modeling compute device 120 may do so by simulating carbon dioxide capture with each of the basalt feed stocks using the models 130 and identifying the basalt feed stock that satisfies the above conditions to the greatest degree.

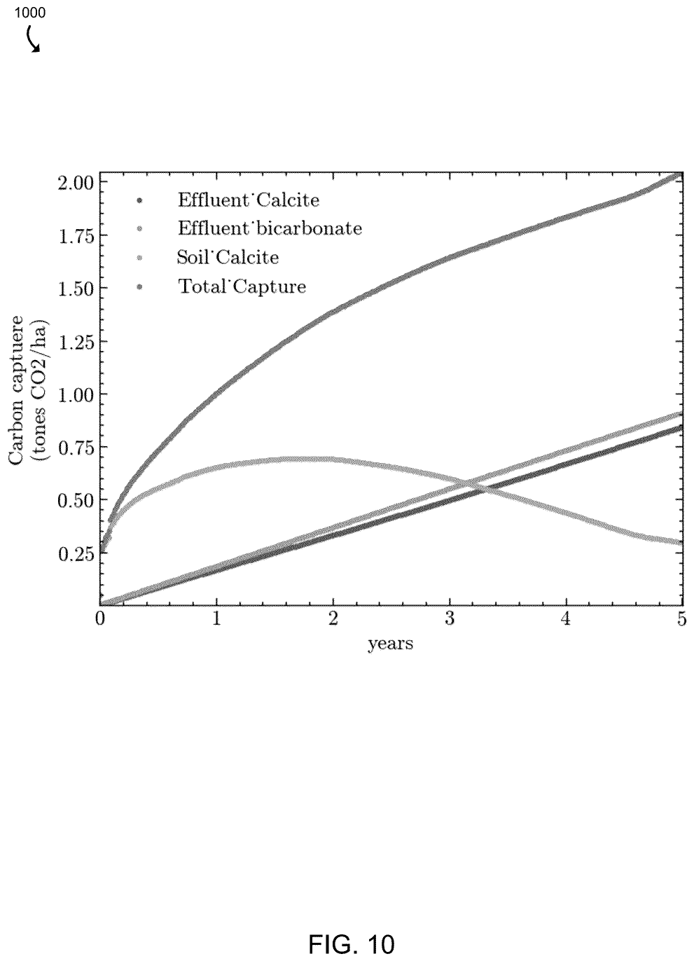

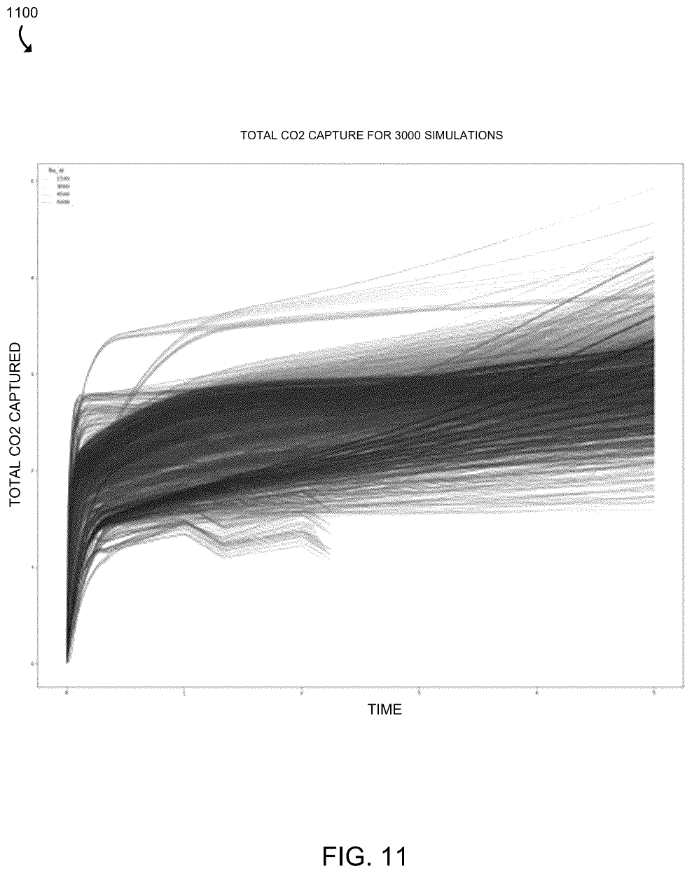

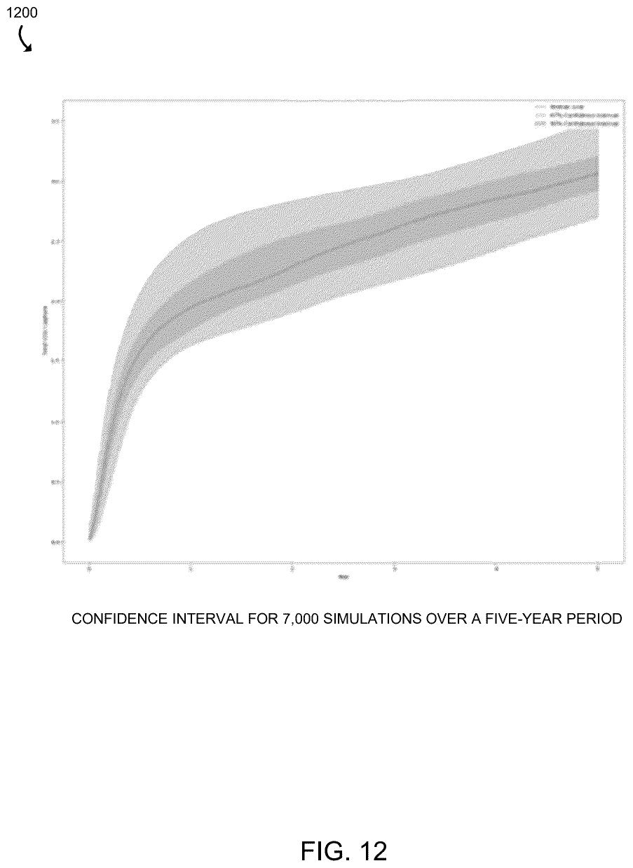

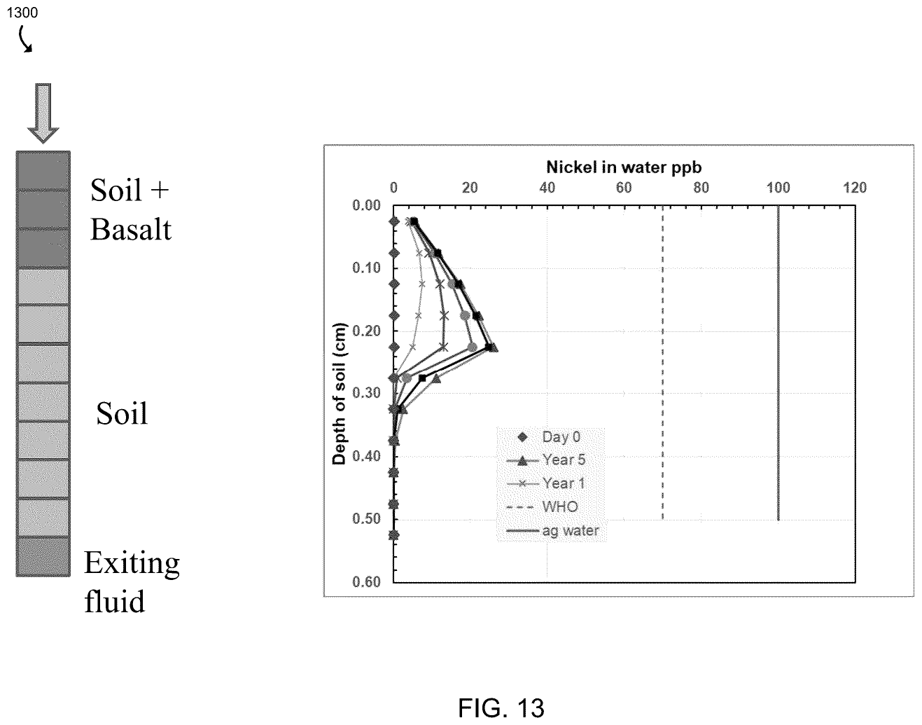

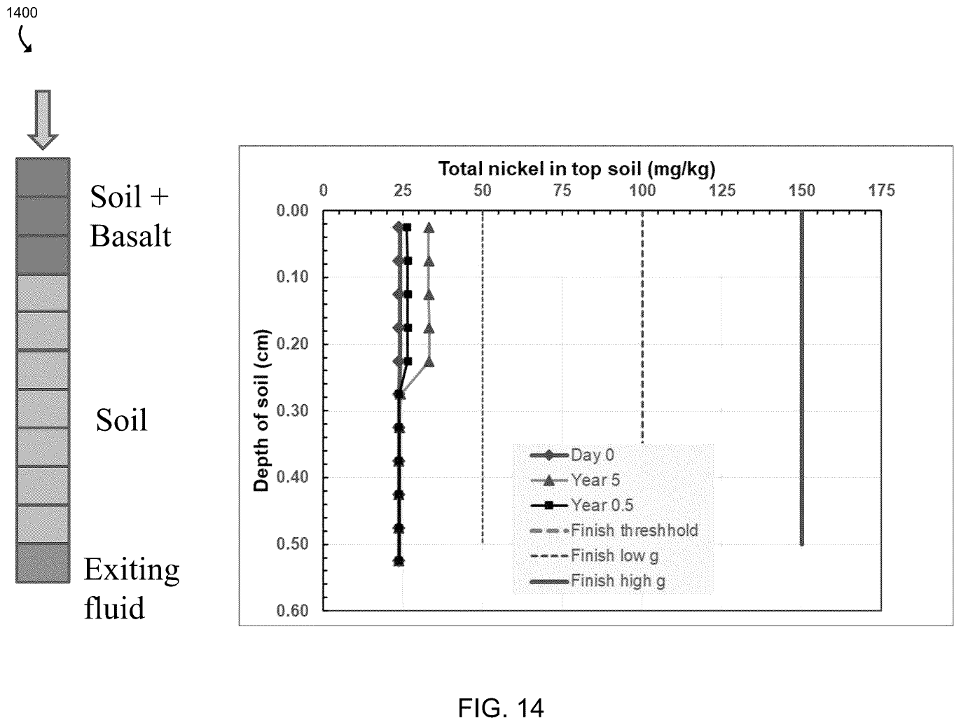

Continuing the method 300, the modeling compute device 120 may present a visual representation of the one or more prediction(s) in a user interface, as indicated in block 412. In the illustrative embodiment, the modeling compute device 120 produces visual presentation(s) of the prediction(s) in a web based interface (e.g., based on a HTML, JavaScript, and image data sent from the modeling compute device 120 to one or more rending engines (e.g., web browser(s)) executed by corresponding target compute devices 150, 152, 154). As indicated in block 416, in producing one or more visual representations of the prediction(s), the modeling compute device 120 may present visual representations that include interactive graphs (e.g., in which time periods, depths, or other parameters may be selected and a corresponding graph is presented). Example embodiments of visual representations 1000, 1100, 1200, 1300, 1400 of the predictions that may be presented by the modeling compute device 120 and displayed by one or more of the corresponding target compute devices 150, 152, 154 are shown in FIGS. 10-14.

While certain illustrative embodiments have been described in detail in the drawings and the foregoing description, such an illustration and description is to be considered as exemplary and not restrictive in character, it being understood that only illustrative embodiments have been shown and described and that all changes and modifications that come within the spirit of the disclosure are desired to be protected. There exists a plurality of advantages of the present disclosure arising from the various features of the apparatus, systems, and methods described herein. It will be noted that alternative embodiments of the apparatus, systems, and methods of the present disclosure may not include all of the features described, yet still benefit from at least some of the advantages of such features. Those of ordinary skill in the art may readily devise their own implementations of the apparatus, systems, and methods that incorporate one or more of the features of the present disclosure.

1. A compute device comprising:
circuitry configured to:
obtain parameter data for use in modeling carbon dioxide removal from the atmosphere through enhanced rock weathering;
produce, using one or more models from a library of models, at least one prediction indicative of an amount of carbon dioxide that will be removed through enhanced rock weathering, including simulating co-precipitation of iron with one or more toxic metals; and
present a visual representation of the at least one prediction in a user interface.

2. The compute device of claim 1, wherein to produce, using one or more models from a library of models, at least one prediction comprises to simulate basalt weathering as irreversible reactions with unidirectional rates.

3. The compute device of claim 1, wherein to produce, using one or more models from a library of models, at least one prediction comprises to utilize one or more models in which near-equilibrium rates are one to two orders of magnitude slower than far-from-equilibrium rates.

4. The compute device of claim 1, wherein to produce, using one or more models from a library of models, at least one prediction comprises to utilize one or more models that simulate co-precipitation of iron with toxic metals.

5. The compute device of claim 1, wherein to obtain parameter data comprises to obtain data indicative of properties of soil in a location where the carbon dioxide is to be captured.

6. The compute device of claim 1, wherein to obtain parameter data comprises to obtain the parameter data as a function of an identification of the location where the carbon dioxide is to be captured.

7. The compute device of claim 1, wherein the circuitry is further configured to calculate, as a function of the obtained parameter data, additional parameter data for use by the one or more models.

8. The compute device of claim 1, wherein to produce at least one prediction comprises to select one or more models as a function of the obtained parameter data.

9. The compute device of claim 1, wherein to produce at least one prediction comprises to select one or more models as a function of a distance of a location where the carbon dioxide is to be captured from one or more reference locations associated with the models in the library.

10. The compute device of claim 1, wherein to produce at least one prediction comprises to utilize one or more machine learning models.

11. The compute device of claim 1, wherein to produce at least one prediction comprises to produce one or more predictions indicative of tons of carbon dioxide captured over a predefined time period.

12. The compute device of claim 1, wherein to produce at least one prediction comprises to produce one or more predictions indicative of tons of carbon dioxide captured per unit of area.

13. The compute device of claim 1, wherein to produce at least one prediction comprises to produce at least one prediction indicative of toxic metal concentrations in water associated with a location where the carbon dioxide is to be captured.

14. A method comprising:
obtaining, by a compute device, parameter data for use in modeling carbon dioxide removal from the atmosphere through enhanced rock weathering;
producing, by the compute device and using one or more models from a library of models, at least one prediction indicative of an amount of carbon dioxide that will be removed through enhanced rock weathering, including simulating co-precipitation of iron with one or more toxic metals; and
presenting, by the compute device, a visual representation of the at least one prediction in a user interface.

15. The method of claim 14, wherein producing, using one or more models from a library of models, at least one prediction comprises simulating basalt weathering as irreversible reactions with unidirectional rates.

16. The method of claim 14, wherein producing, using one or more models from a library of models, at least one prediction comprises utilizing one or more models in which near-equilibrium rates are one to two orders of magnitude slower than far-from-equilibrium rates.

17. The method of claim 14, wherein producing, using one or more models from a library of models, at least one prediction comprises utilizing one or more models that simulate co-precipitation of iron with toxic metals.

18. The method of claim 14, wherein obtaining parameter data comprises obtaining data indicative of properties of soil in a location where the carbon dioxide is to be captured.

19. One or more machine-readable storage media comprising a plurality of instructions stored thereon that, in response to being executed, cause a compute device to:
obtain parameter data for use in modeling carbon dioxide removal from the atmosphere through enhanced rock weathering;
produce, using one or more models from a library of models, at least one prediction indicative of an amount of carbon dioxide that will be removed through enhanced rock weathering, including simulating co-precipitation of iron with one or more toxic metals; and
present a visual representation of the at least one prediction in a user interface.

20. The one or more machine-readable storage media of claim 19, wherein to obtain parameter data comprises to obtain data indicative of properties of soil in a location where the carbon dioxide is to be captured.
